(19) United States
(12) Patent Application Publication
(10) Pub. No.: US 2026/0187314 A1
(43) Pub. Date: Jul. 2, 2026

(54) TRAINING A LEARNING ALGORITHM FOR SIMULATED SITING OF A COLOCATED NEW ENERGY GENERATION FACILITY WITH AN INDUSTRIAL LOAD

(71) Applicant: Inventus Holidngs, LLC, Juno Beach, FL (US)

(72) Inventors: Nicholas C.W. Hemlock, Juno Beach, FL (US); Keith J. Harding, Minneapolis, MN (US); Lowell C. Savage, Juno Beach, FL (US); Alexander A.D. Kirsch, Mineapolis, MN (US); Ross A. Weinstein, Juno Beach, FL (US); Norma J. Farah, Juno Beach, FL (US); Kayla S. Campbell, Juno Beach, FL (US)

(21) Appl. No.: 19/005,137

(22) Filed: Dec. 30, 2024

(51) Int. Cl. G06F 30/27; G06Q 50/08

(52) U.S. Cl. CPC G06F 30/27; G06Q 50/08

(57) ABSTRACT

A system and computer-implemented method that trains a learning algorithm to simulate the siting of new energy generation facilities colocated with a recommended industrial load on a subset of land parcels. The method begins by running simulations to evaluate land parcels based on characteristics such as electricity transmission, market demand, and industrial load usage. A clustering algorithm uses these characteristics to generate a training set predicting electricity output from the facilities on the selected land parcels. Each subset is assigned a combined score, factoring in its size, transmission distance, and projected revenue, with higher scores indicating better suitability. The scores are ranked, and changes in land parcel characteristics are monitored. If changes exceed a set threshold, the algorithm is re-trained using updated characteristics. This process enables the method to adapt dynamically, refining recommendations for siting energy facilities in response to evolving conditions and maximizing both efficiency and profitability.

### FIELD OF THE DISCLOSURE

The present invention generally relates to using machine learning to analyze parcels of land for the development of energy projects, namely wind farms, solar farms, energy storage systems, small modular reactors (SMRs), gas-fired electricity generation facilities, and more particularly, relates to training a machine learning algorithm to simulate the siting of a new energy generation facility colocated with an industrial load.

### BACKGROUND

The development of advanced microchips and technologies like ChatGPT has revolutionized Generative AI, driving significant advancements in the field. However, these highly complex models demand substantial electricity, potentially placing a considerable strain on the power grid.

Hyperscalers, or large data center companies, must carefully evaluate where on the grid to establish their data centers and the power plants that supply them. A growing preference for renewable energy adds another layer of complexity, as siting suitable renewable energy sources becomes a critical consideration.

Similarly, the expansion of semiconductor manufacturing to meet the demands of AI has led to a rapid increase in factory construction. These facilities also prioritize sourcing electricity from renewable energy providers.

Developing utility-scale energy projects, such as wind farms, solar farms, energy storage systems, small modular reactors (SMRs), and gas-fired electricity generation facilities takes time. The development stage includes planning and site acquisition, transmission studies and interconnect agreement with the utility, negotiation of the power purchase agreement with a prospective off-taker, transmission permitting, generating permitting and approval, and financing.

To produce energy projects for specific utility-scale generation capacity, typically in Megawatts (MW), parcels of land must be reviewed. Identifying the best energy sites across a large geographical area (e.g., the United States) is difficult because many factors, including resource, land, transmission, and market considerations, may render a site not economically viable.

### SUMMARY OF THE INVENTION

A computer-implemented method trams a learning algorithm to simulate the siting of multiple new energy generation facilities colocated with a recommended industrial load on a subset of land parcels. The method begins by executing a total number of simultaneous simulations (M) for the new energy generation facilities and the recommended industrial load on the subset of land parcels. This involves accessing various characteristics associated with each land parcel, including electricity transmission characteristics, market demand characteristics, and the industrial load using electricity from the facilities. A clustering algorithm is then applied to these characteristics to create a first training set that predicts the expected electricity output from the facilities on the subset of land parcels to meet the colocated industrial load. A combined score is calculated for each subset of land parcels, with the score including a first component directly proportional to the cumulative size of the subsets, a second component inversely proportional to the length of the electricity transmission characteristic, and a third component directly proportional to the projected annual revenue based on market demand.

The method proceeds by ranking the combined scores in an ordered list, prioritizing subsets with higher scores. It then identifies any changes in the characteristics of one or more land parcels and evaluates whether these changes exceed a settable threshold. If the change is determined to exceed the threshold, the clustering algorithm is re-trained using the updated characteristics. This re-training involves re-executing the initial steps to generate a second training set based on the updated characteristics.

The criteria of transmission characteristics for each parcel of land in the portfolio may include the size of substation hardware costs, network upgrade costs, or grid tie-in costs.

Further the criteria of market characteristics e.g., hourly locational marginal prices can be combined with resource characteristics to simulate annual revenue conditional on the timing of wind and/or solar resources and fluctuations in locational marginal prices for each land parcel.

The results may be displayed in various formats with various color overlays on maps illustrating the combination of the parcels of land with the highest ranking for development based on the criteria.

The recommended industrial load may be a new prospective industrial load, a preexisting industrial load, or a preexisting industrial load that is being updated.

### BRIEF DESCRIPTION OF THE DRAWINGS

The accompanying figures, where like reference numerals, refer to identical or functionally similar elements throughout the separate views, and which, together with the detailed description below, are incorporated in and form part of the specification, serve to further illustrate various embodiments and to explain various principles and advantages all in accordance with the present disclosure, in which:

FIG. 1 illustrates a combination of renewable energy sources, specifically wind, solar, and battery, on a parcel of land, as known in the prior art;

FIG. 2 illustrates large areas of renewable energy sources using solar across many acres and parcels of land that form a non-rectangular shape, as known in the prior art;

FIG. 3 depicts a pictorial overview of the process for training a learning algorithm for the simulated siting of a new energy generation facility, according to an example of the present invention;

FIG. 4 depicts a pictorial view of different multi-county regions in the continental USA based on ReEDs capacity, according to an example of the present invention;

FIG. 5 depicts a table view of a cluster in the State of Oklahoma, according to an example of the present invention;

FIG. 6 depicts a graph of transmission costs versus transmission scores, according to an example of the present invention;

FIG. 7A depicts a pictorial map of color-coded land score values with various filters for a 150 MW wind farm and FIG. 7B depicts a pictorial map of color-coded land score values, as in FIG. 7A, but for the overall score, according to an example of the present invention;

FIG. 8 depicts a graph of parcel size score versus landowner's parcel size, according to an example of the present invention;

FIG. 9 depicts a graph of an owner count score versus the number of owners for solar and wind, according to an example of the present invention;

FIG. 10 depicts a graph of the buildable area score versus the percentage of buildable land in a search radius, according to an example of the present invention;

FIG. 11 depicts a graph of the land value score versus parcel value, according to an example of the present invention;

FIG. 12 depicts a series of pictorial diagrams representing parcel sentiment score, parcel sentiment score boost, land parcel clusters, and cluster sentiment score boost, according to an example of the present invention;

FIG. 13 depicts a graph of sentiment score adder versus unadjusted score based on the type of land listing, according to an example of the present invention:

FIG. 14A and FIG. 14B depicts are pictorial maps of color-coded sentiment boost score values with various filters, according to an example of the present invention;

FIG. 15 depicts an example of an interactive user interface that illustrates a pictorial color-coded map of solar prospects recommended by the system with buildable land highlighted, according to an example of the present invention;

FIG. 16 depicts an example of an interactive user interface that illustrates a pictorial map of color-coded recommended clusters of land parcels for a wind project, including overall score characteristics, plus resource characteristics, land characteristics, transmission characteristics, and other sub-scores, according to an example of the present invention;

FIG. 17 depicts an example of an interactive user interface that illustrates a pictorial map of color-coded recommended clusters of land parcels for a wind project, including overall score characteristics, plus scores for resource characteristics, land characteristics, and transmission characteristics, as well as landowner sentiment, according to an example of the present invention;

FIG. 18 is a flow chart for identifying parcels of land for an energy generation facility, according to an example of the present invention;

FIG. 19A and FIG. 19B is a flow chart 1900 for training a learning algorithm for simulated siting of a colocated new energy generation facility, according to an example of the present invention;

FIG. 20 depicts an example of an interactive user interface that illustrates a delineated set of land parcels recommended for a new small modular reactor (SMR) site, including overall score characteristics, plus scores for resource characteristics, land characteristics, and transmission characteristics, as well as landowner sentiment, according to an example of the present invention; and

FIG. 21 illustrates a block diagram illustrating a processing system for carrying out portions of the present invention.

### DETAILED DESCRIPTION

As required, detailed embodiments are disclosed herein; however, it is to be understood that the disclosed embodiments are merely examples and that the systems and methods described below are embodied in various forms. Therefore, specific structural and functional details disclosed herein are not to be interpreted as limiting but merely as a basis for the claims and as a representative basis for teaching one skilled in the art to variously employ the disclosed subject matter in virtually any appropriately detailed structure and function. Further, the terms and phrases used herein are not intended to be limiting but rather to provide an understandable description.

### Overview

Aspects of the present invention include training a learning algorithm to simulate the siting of colocated energy generation facilities and industrial loads, such as data centers or manufacturing sites. The trained algorithm identifies optimal locations for constructing energy generation facilities to power industrial loads, addressing different project stages: brand-new prospects (“greenfield”), early-stage projects, and late-stage projects. Here, “greenfield” prospects refer to clusters of land parcels aggregated by the algorithm to meet a specified power capacity requirement for the data center, such as 50 MW.

The trained algorithm ranks potential locations based on factors such as wind and solar resource availability, transmission costs for energy generation and delivery to the data center, and transmission accessibility. Transmission accessibility encompasses proximity to key infrastructure, including railroads, highways, and airports, which are particularly critical for semiconductor manufacturing. Additionally, the algorithm evaluates wholesale market conditions, such as Locational Marginal Prices (LMPs), population density, and local water stress, ensuring sustainable water use in regions prone to scarcity. Furthermore, the algorithm prioritizes locations with strong fiber connectivity to support data center operations and accounts for population density to balance labor availability and community impact.

The system incorporates several interactive graphical user interfaces (GUIs) to facilitate user input and automatically generate a visual delineation around the land parcels based on specific criteria indicating a highest combined score to meet the electricity requirements for a new energy generation facility. The process leverages the trained algorithm to display a series of dynamic screens, effectively presenting a “movie” of the simulated siting process on a map in real-time. The system can automatically generate and position delineations over combinations of land parcels on the displayed map, illustrating each simulated siting in the sequence. Note that not all iterations need to be shown. Rather only iterations that improve over previous iterations or every ten iterations may be shown. The system may automatically generate and position a delineation over the combination of land parcels on the map displayed on the GUI of the series of simulated sitings.

### Non-Limiting Definitions

Generally, the terms “a” or “an”, as used herein, are defined as one or more than one. The term plurality, as used herein, is defined as two or more than two.

The term “adapted to” describes the hardware, software, or a combination of hardware and software that is capable of able to accommodate, to make, or that is suitable to carry out a given function.

The term “another”, as used herein, is defined as at least a second or more.

The term “configured to” describes the hardware, software, or a combination of hardware and software that is adapted to, set up, arranged, built, composed, constructed, designed, or that has any combination of these characteristics to carry out a given function.

The term “coupled,” as used herein, is defined as “connected,” although not necessarily directly and not necessarily mechanically.

The term “displaying in real-time” refers to the capabilities of computers to analyze vast amounts of data and, after completing the analysis, present results to a display with no noticeable delay. This is something no group of humans can do at that speed or scale.

The term “fatal flaw” or “low score escalators” means that one of the land characteristics for a given parcel of land makes it entirely undesirable for development, even if the other land characteristics score high. For example, if the landowner is listed as a US National Park, this parcel of land, in general, is not feasible for development.

The term “independent system operator” or “ISO” is an organization formed at the recommendation of the Federal Energy Regulatory Commission. In the areas where an ISO is established, the ISO coordinates, controls, and monitors the operation of the electrical power system, usually within a single LUS state but sometimes encompassing multiple states. Regional Transmission Organizations (RTOs) typically perform the same functions as ISOs but cover a larger geographic area.

The terms “including” and “having” as used herein, are defined as comprising (i.e., open language).

The term “land characteristics” includes size, ownership, tree coverage, elevations, terrain, buildable land, location of nearby renewable projects, and the owner's willingness or sentiment to sell rights.

The term “load” means an item that consumes electricity, at least part of the time. Examples of loads include electrolizers, data centers, manufacturing plants, and battery storage farms (when they are charging).

The term “locational marginal pricing” or “LMP” is adapting wholesale electric energy prices to reflect the value of electric energy at different locations, accounting for the patterns of load, generation, and the physical limits of the transmission system.

The term “NEE” is an abbreviation for NextEra Energy and “NEER” is an abbreviation for NextEra Energy Resources, a subsidiary of NEE.

The term “net capacity factor” or “NCF” is the ratio of actual electrical energy output over a given period of time divided by the theoretical continuous maximum electrical energy output over that period.

The term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

The term “resource characteristics” includes the net capacity factor (NCF) of wind or solar, which describes the fraction of total capacity that is produced over the course of a typical year. Typical total capacities include 20, 25, 50, 75, 100, 150, 200, 250, and 400 Megawatts (MWs). Note solar capacities are typically on the lower end, and wind capacities are typically on the higher end of these typical capacities.

The term “simultaneous” means computations are carried out at the same time, which for larger data sets with various constraints, is not possible to be carried out completed by a group of humans and must be performed by a computer. For example, a group of humans could not compute one simulation with all the constraints for thousands of various clusters of parcels of land across multiple counties and across multiple states with all the various criteria. It is infeasible for a human to calculate one simulation loop with one constraint, let alone perform it in parallel to a sort of global optimum.

The term “site and size” refers to the suggested location to place a system. The system can be either an energy generation system or an industrial load. The term size refers to the capacity. The capacity, typically measured in MegaWatts, is the output of an energy generation system or the required input for an industrial load.

The term “transmission characteristics” includes substation hardware costs, network upgrades, and grid tie-in costs, such as those to be compatible with Federal Energy Regulatory Commission Order 845.

The term “uniform data format” means data in a given format, whether date format, time format, currency format, scientific format, text format, or fractional format, so that all values of data are presented in a single consistent format for a given category or criteria.

It should be understood that the steps of the methods set forth herein are not necessarily required to be performed in the order described, and the order of the steps of such methods should be understood to be merely exemplary. Likewise, additional steps may be included in such methods, and certain steps may be omitted or combined in methods consistent with various embodiments of the present device.

Although the elements in the following method claims, if any, are recited in a particular sequence with corresponding labeling unless the claim recitations otherwise imply a particular sequence for implementing some or all of those elements, those elements are not necessarily intended to be limited to being implemented in that particular sequence.

### Overview

Disclosed is a system for identifying a broad range of utility-scale energy sites that are likely to be profitable and successful across the whole country based on a ranking algorithm that is displayed within a user interface (UI). The system provides developers with actionable information that increases the likelihood of project success while reducing the time to conclude recommended clusters of land parcels and a streamlined user interface that provides information not readily available.

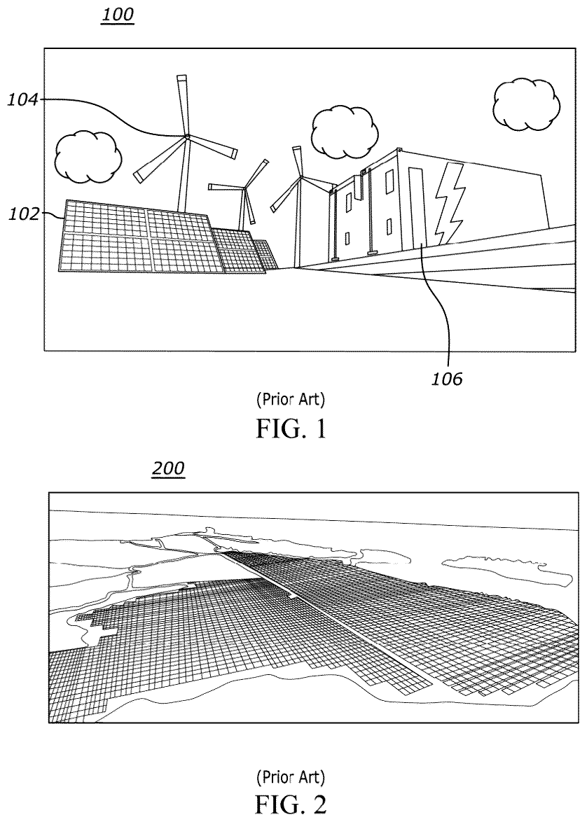

Turning to FIG. 1, a combination of renewable energy sources is shown (100). More specifically, shown are solar arrays 102, wind turbines 104, and battery storage 106. The present invention provides a method and system for identifying suitable combinations of parcels of land to construct these types of facilities.

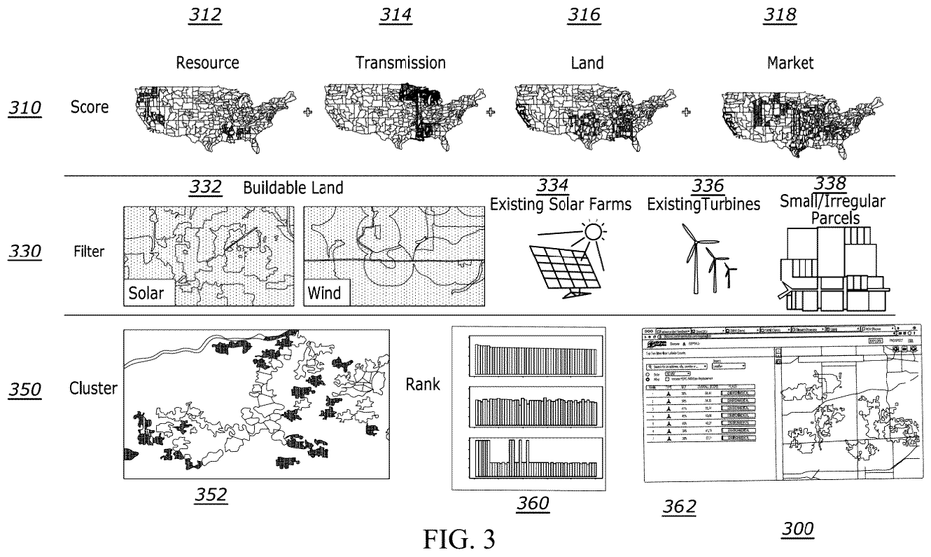

FIG. 2 illustrates large areas of renewable energy sources 200 using solar across many acres and parcels of land that form a non-rectangular shape.

### Pictorial High-Level Overview

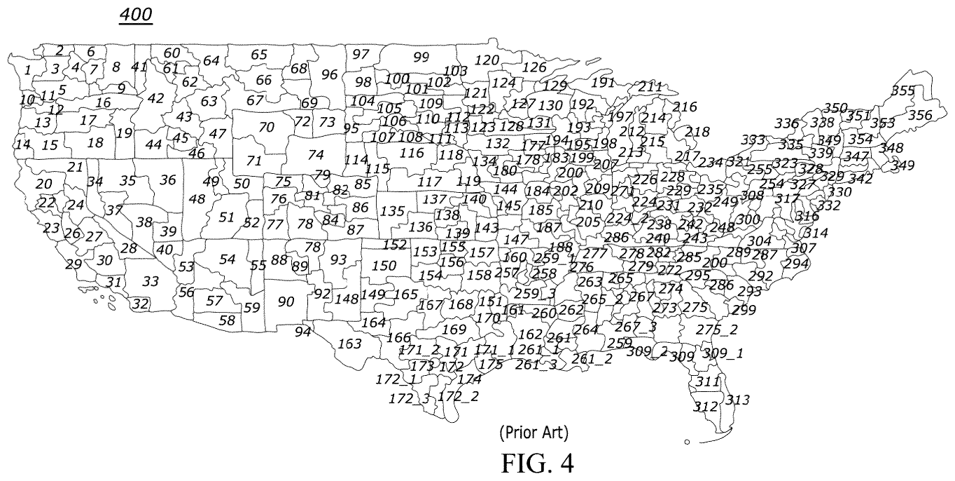

A high-level overview of one example of training a learning algorithm for the simulated siting of a new energy generation facility is shown in FIG. 3. More specifically, FIG. 3 depicts a pictorial overview 300 of the process. The process begins by looking at a variety of characteristics for each land parcel in a portfolio of land parcels. Characteristics include resource characteristics 312, transmission characteristics 314, land characteristics 316, and market characteristics 318. Next, filters 330 are applied to each parcel of land. Filters include buildable land 332, distance to nearby or existing solar 334, wind turbines 336, and irregular and small parcels 338. After filters in 330, the machine learning algorithm is trained using clustering 350. The clustering algorithm 352 uses the characteristics to produce a first training set that includes an expected electricity output for the type of new energy generation facility on one or more subsets of the plurality of land parcels; calculating a respective combined score for each subset of land parcels, wherein the combined score comprises a first score directly related to the cumulative size of the subsets of land parcels, a second score inversely related to the length of the electricity transmission characteristic, and a third score directly related to the projected annual revenue of the market demand characteristic. The results are ranked 360 as meeting an electricity requirement combined with the highest combined score of a cumulative size of the subset of the parcels of land in the portfolio, the electricity transmission characteristics, and the market demand. If the characteristics for any land parcel change beyond a set threshold, the machine learning model is re-trained by re-executing the steps with the clustering algorithm using the updated characteristics as a second training set. These rankings are shown in interactive user interface 360, with color coding, charts, and other information, including overlays of maps 362.

In one example, the system includes a prospecting tool that ranks every land parcel in the country based on the high-level characteristics that influence project viability. The goal is to improve the odds of a prospect getting built and to reach a quicker conclusion.

The system combines all of the high-level factors to evaluate a successful prospect. Optional features may include: i) land parcel ownership, ii) evaluations extend nationwide in land parcel review, and iii) displaying relevant data layers that identify nearby features of significance.

The total score combines sub-scores, representing how feasible different components are, and can be adjusted for various types of prospects. For example, this prospecting tool is used for industrial loads, such data centers and battery energy storage site selections, and additional types of prospects of new energy facilities for a cluster of land are planned.

The combined score means that a very low score in one category allows the tool to avoid “fatal flaws” with projects. That is, the identification of a potential “fatal flaw” is such that it ranks a group of land parcels much lower, eliminating them from consideration. For example, the fatal flaws may include very high transmission costs, very long gen-tie lines, and too many landowners in an area.

For each cluster of land parcels, the system provides an overall score, which is a weighted value based on individual scores for resource, land, transmission, and market characteristics. The sub-scores and overall scores may be presented to the user in the U 1. Users can initiate a utility-scale wind, solar, battery, or SMR prospect within the user interface based on recommended clusters of land parcels, drawing their own candidate, or uploading external geospatial files.

The system quantifies the tradeoffs between resource, transmission, market, and land constraints that influence whether wind and/or solar projects are successful. The ranking system identifies the best clusters of land parcels sufficient to build a utility-scale energy project and identifies those with the best combination of resource, transmission, and market characteristics while maximizing buildable land and minimizing landowners. In one example, the system evaluates enough clusters of land parcels to build 29 Terawatts of solar capacity spread across 1.1 million virtual solar farms and 5 Terawatts of wind capacity across 100,000 virtual wind farms across the contiguous United States. The virtual or potential wind and solar farms being ranked could provide 25 times the US total electricity capacity, giving developers a cache of actionable intelligence that can improve the wind and solar development process to significantly reduce carbon emissions of America's electric power generation critical infrastructure.

### Utility-Scale Wind/Solar Algorithm

The overall goal of land parcel clustering is to identify and recommend clusters of parcels that have sufficient transmission, resources, market demand, and available land to build a wind or solar farm. Land characteristics (Land Score), transmission characteristics (substation hardware costs, network upgrades, gen-tic cost), market characteristics (historical LMPs), and resources (wind/solar NCF) are considered in producing clusters of land parcels that minimize the number of landowners, maximize buildable land, minimize transmission cost, maximize NCF, and maximize nodal LMPs.

### Standalone Storage Algorithm

In one example for siting a battery storage facility, the present invention brings together factors used for other types of new energy generation facilities, including wind farm, solar farm, and SMRs. For battery energy storage energy generation facilities other factors may include the proximity to the substation, battery arbitrage opportunities, and land parcel characteristics (buildable land and building footprints) that influence the viability of standalone storage prospects, ultimately recommending the best properties to pursue these projects. The ultimate goal is to provide battery prospectors with recommendations for land parcels that have sufficient open land near substations and good arbitrage opportunities. The system is also designed to generally highlight land and transmission characteristics more than market/arbitrage characteristics (until additional and more comprehensive arbitrage/load data), so users can pan on the user interface map based on displayed arbitrage values and then zoom into the appropriate scale for prospecting.

### Technical Document

The overall goal of the land parcel clustering algorithm is to codify all of the major influences on different energy projects viability for every land parcel in the country based on interviews with developers, historical analyses, and financial/physical relationships. The present invention produces a trained algorithm for identifying and recommending clusters of parcels with sufficient transmission, resources, market demand, available land, and positive landowner sentiment to build a utility-scale energy project. Developers see the clusters of parcels in a given area that have the best chance of culminating in a constructed energy project without showing any areas with insufficient land for construction. In training the clustering algorithm, the main goals are to 1) provide reasonable compact clusters of parcels with minimal landownership and 2) score those clusters with the appropriate tradeoffs between transmission, resource, market demand, suitable/advantageous land, and landowner sentiment. Here, details about the clustering and considerations as development continues are considered.

Overall, the system filters and ranks all land parcels throughout the country based on a combination of transmission/land/market/resource scores and then clusters them together to form enough buildable land to build an energy project of different capacities. All clusters of land parcels are then scored based on their transmission/land/market/resource scores. Within the GUI, users can then view the top N clusters of land parcels for these energy projects of a given capacity within the geographic area displayed in the user interface, wherein N can be a default number or preset by a user.

### Documentation of Algorithm

The land parcel clustering process starts with reasonable objective assumptions that inform the weighting of score components and filtering of parcels. The process then continues by modifying the weighting of score components (resource/transmissionvmarket/land as well as the components of the land score) to force the most appropriately shaped and ranked clusters.

### Development of Clustering Algorithm

Do the top N options represent an appropriate mix of good transmission, good land, and good resources. Determine whether the weighting/filtering penalizes clusters that have very low scores in transmission, resource, or land. Examples of weighting/filtering penalizes clusters may include:
Great transmission but low available land/high land parcel density: retiring plant surrounded by acreages.
Great land but surrounded by full substations.
Great land but a very poor resource, such as low wind, prone to flooding, too rugged of terrain to build, too many trees, and more.
Great resource but poor availability of land. For example, the following types of clusters may appear: many different landowners or sparse buildable land.
Most appropriate weights that replicate variations in tax-efficient Levelized Cost of Energy (LCOE) and Lcvclized Cost of Transmission (LCOT).
Modify weights based on examination of tradeoffs in cluster rankings.

### Process Begins

In one example, the process begins with identifying the technology type, such as solar farm, wind farm, energy storage facility, or SMR facility, and the capacity desired.

### Load Nationwide Data

The process starts by loading nationwide gridded “ranker data” (nationwide grids of resource, transmission, and market characteristics/scores) that are produced by solar farm locations, wind turbine locations, and data intelligence and marketplace listings for land. Marketplace listings of land is a database marketplace for listing sale or lease of land, that may include other information useful for developing new energy generation facilities such as wind, solar, battery and SMRs. Data gathered is arranged on a 1×1 km grid for solar over the continental USA and on a 2×2 km grid for wind.

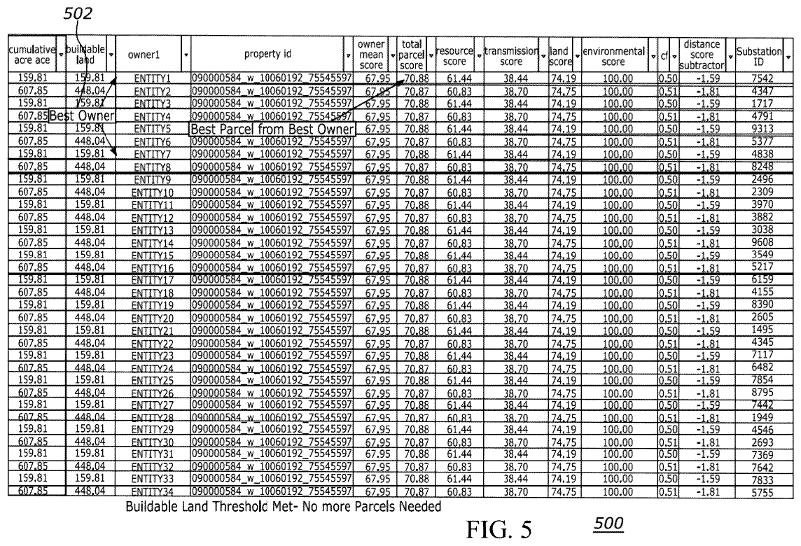

Turning to FIG. 4 depicts a pictorial view 400 of the different multi-county regions in the continental USA derived from resource supply regions from NREL's Renewable Energy Deployment System (ReEDs), according to an example of the present invention.

### Loop Over Different Counties Across the Continental USA.

In one example, the system runs nationwide. However, it loops over 3,144 different counties in the country,

### Load Regional Data, Subset Region Data, And Merge Together

While in a particular clustering region, all of the filtered land parcel data, buildable land data, and tree cover data (if applicable) are loaded and merged together with the gridded “ranker data” and marketplace land listings. In this manner, statistics about every single filtered land parcel in the region is processed, including parcel metadata, transmission costs/scores, market scores, NCFs, resource scores, total tree coverage (if applicable), buildable land area, Marketplace land listings, etc.

### Score Land Parcels

All land parcels in a region are then scored based on the various criteria including a first score directly related to the cumulative size of the subsets of land parcels, a second score inversely related to the length of the electricity transmission characteristic, and a third score directly related to the projected annual revenue of the market demand characteristic. The land parcels are prepped in a uniform data format for clustering, which will be done for all filtered land parcels in a region.

### Build all Possible Clusters Centered on Every Single Filtered Land Parcel

After loading and merging all the data, the system tries to build clusters starting at all land parcels of sufficient size (e.g., >5 acres) in the function for a given project capacity, where the system searches for all land parcels within a small radius (that scales by the project capacity). The system then ranks and sorts the parcel scores grouped by the landowner and land parcel scores within a search radius (scaled to the capacity of the project). Next, the highest score parcels are selected from each owner until a sufficient buildable acreage is collected to support the construction of an energy project of a given capacity. If not enough buildable land exists to build an energy project of a given capacity, no clusters are built, and the system moves on to the next starting land parcel. The system also uses a distance score that adjusts all land parcels within the small search radius based on the distance from the centroid land parcel (starting parcel) and the distribution of scores in the search radius. This allows clusters to be generally more compact when they are initially built but has no impact on which clusters are eventually chosen when all possible clusters are ranked.

A distance score (i.e., a temporary score) is introduced to give more weight to land parcels closer to the “starting land parcel.”

To encourage the choice of parcels closer to the center of each cluster, a score is assigned to each parcel based on the distance from the starting parcel. This distance score is used only when sorting parcels and not in the final land score or total score.

The “distance_score_subtractor” is simply the standard deviation (scores within the search radius for each cluster) multiplied by the distance from the starting parcel centroid/search radius. This distance_score_subtractor is only applied when sorting by owner in the parcel clustering.

To get the mean owner count score (defined further below) for the parcel clustering, the mean of all parcels by owner is calculated plus the minimum “distance_score_subtractor” for parcels associated with that owner. That way, the best parcels from owners that are generally close to the starting parcel are prioritized.

The distance score is meant to prioritize landowners (and their parcels) closer to the center of the search radius, which produces more contiguous clusters in areas with many landowners. Because the system gathers parcels together by groups of landowners, the distance score generally has a negligible impact on the number of landowners but instead has a large impact on which landowners are chosen in areas with many owners of small parcels (the system will choose owners closer to the center of the search radius).

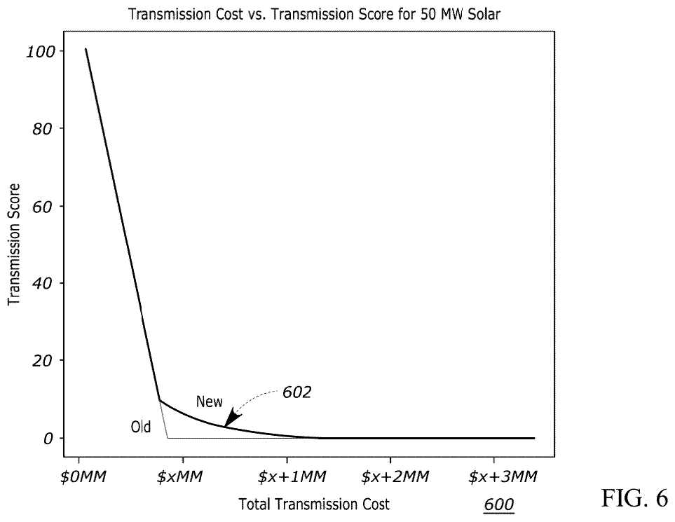

FIG. 5 depicts a table view 500 of a cluster in Oklahoma. Note that the top three owners 502, appear to be the same but are structured differently.

### Rank all Possible Land Parcel Clusters

After building clusters around all filtered parcels with enough buildable land in the search radius, the system sorts the clusters by score and removes any overlapping clusters with lower scores. The system iteratively chooses the best non-overlapping clusters until none are left or the specified number of clusters has been chosen. The system also adds some ranking information to the output and formats/filters the output, saving the output as a file for a national aggregation later.

### National Aggregation and Normalization

After all the regions have been run, the file outputs from each region are loaded sequentially, and then scores are normalized to a final 0-100 score.

All national files are outputted to local or cloud storage, and the data is ingested into the UI.

### Filtering

Filtering allows objective removal of non-buildable areas and tries to consider edge cases where appropriate without being too restrictive. Areas that provide marginal or atypical development potential are kept in the system but are generally scored lower.

### Wind Filters

The wind filter removes unviable land for a wind project based on one or more of the following criteria. One example for identifying wind buildable land makes use of a geospatial database. The geospatial database is a collection of land areas that can technically support the construction and permitting of wind turbines based on sufficient setbacks from existing building footprints, transportation corridors, transmission lines, pipelines, airports, protected lands, critical habitats, wetlands, operating wind farms, city limits, and areas prone to frequent flooding.

The wind filters remove existing wind farms within a buffer, extreme elevation, and long distance.

### Solar Filters

The solar filter removes unviable land for a wind project based on one or more of the following criteria. One example for identifying solar buildable land makes use of a geospatial database. The geospatial database is a collection of land areas that can technically support the construction and permitting of solar farms based on sufficient setbacks from existing building footprints, transportation corridors, transmission lines, pipelines, and other limiting factors

Solar filters removes parcels with small amounts of buildable land (scaled to farm size due to computing limitations) and based on a variety of considerations, including elevation, parcel shape and size, among others.

### Assumptions

The assumptions for wind are made for parcels of land based on one or more of the following criteria.

Assumptions for wind include Wind Farm Land Density (land_density). Capacity needed e.g. Capacity: 50, 100, 150 MW. Buildable_frac_in_radius is the fraction of buildable land required in the search radius for building a cluster. If not enough options are showing up in an area, then the search radius can be increased by reducing Buildable_frac_in_radius. Search radius (in km):(([1/buildable_frac_in_radius]*land_density*Capacity)/(247*pi)), where 247 is the number of acres per square kilometer. It is the radius of a circle that makes an area large enough to produce n(1/buildable_frac_in_radius) times the buildable land needed.

Assumption for solar include Solar Farm Land Density (land_density). Capacity: 50, 100, 150 MW. Buildable_frac_in_radius is the fraction of buildable land required in the search radius for building a cluster. If not enough options appear in an area, then the search radius can be increased by reducing Buildable_frac_in_radius_Search radius (in km): (([1/buildable_frac_in_radius]*land density*Capacity)/(247*pi)), where 247 is the number of acres per square kilometer. It is the radius of a circle that makes an area large enough to produce n (1/buildable_frac_in_radius) times the buildable land needed.

### Score Components and Apply Weights

### Resource Score

The Resource Score (100=best, 0=worst) describes the relative strength of the wind/solar resource over a given cluster of land parcels. It is calculated by converting NCF estimates for each solar and wind grid cell into a 0-100 score. Wind and solar NCPs distributions are extended from the 5th percentile to the maximum to get 0-100 scores for wind and solar independently. Resource scores are calculated for each land parcel based on weighted area averages of grid cells within a parcel, which helps determine which parcels are chosen by the clustering algorithm.

### Transmission Score

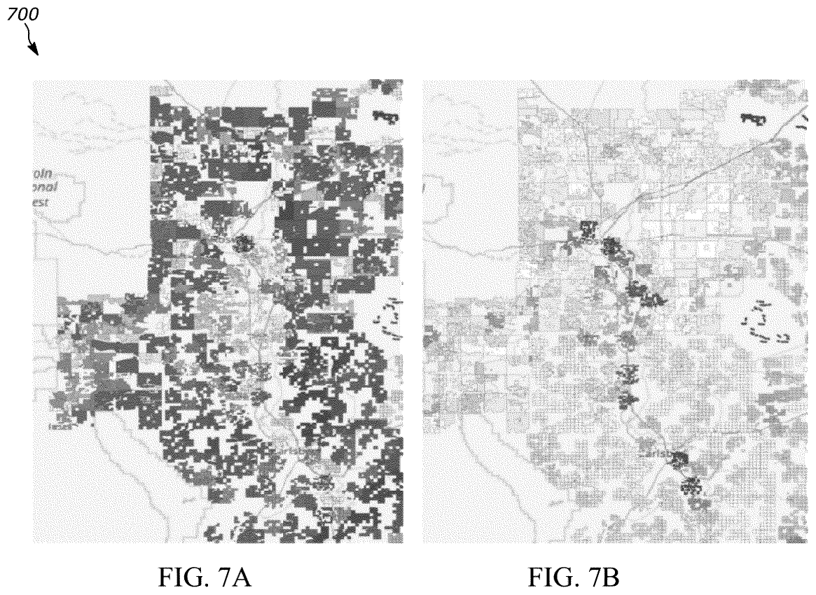

FIG. 6 depicts a graph of transmission costs versus transmission scores 600, according to an example of the present invention. The Transmission Score (100=best, 0=worst) describes how characteristics of the transmission network (congestion, queue positions, substation/tap costs, gen-tic line length) can ease project advancement or present barriers to development. It is calculated by converting the sum of the network upgrade costs, interconnection facility cost, and cost to a 0-100 score for the cheapest bus out of the 100 closest intrastate busses or the cheapest line tap. Gen-tie line is an industry term that means the generation-intertie overhead electric line that will connect the wind/solar project substation to the utility substation owned by the transmission owner. Note that region 602 illustrates the exponential score decay, which enables gen-tie length to influence the score at a very high cost.

The transmission score of a cluster is based on the highest transmission score from any of the closest gridded points (transmission scores are calculated for wind and solar grids) within the cluster, whether that connection is to an existing substation or for a new line tap.

### Market Score

The Market Score quantifies the market conditions for developing wind or solar in a given location. This is determined by calculating a percentile of generation-weighted LMPs (for wind and for solar) using hourly energy time series and hourly historical LMPs from analytical software for the energy industry. The system then converts them to a 0-100 score by converting the distribution of generation-weighted LMPs to 0-100 within each ISO.

The market score of the highest-scoring bus (based on the weighted average of transmission score and market score for all gids in the cluster) for any grid point within the cluster.

### Land Score

The Land Score (100=best, 0=worst) describes the land characteristics that influence the feasibility of completing a project. The Buildable Land Score is a 0-100 score that scores the amount of buildable land in the vicinity (0=least land, 100=most land). The Land Cost score estimates the relative cost of tree clearing costs on a land parcel. The Environmental Score uses a count of relevant environmental layers from the Nature Conservancy, converted to a 0-100 score (0=most layers, 100=no layers), for each parcel and averaged over the cluster.

Sum of land score components (see below), which are a mix of weighted area averages of parcels and cluster summary statistics.

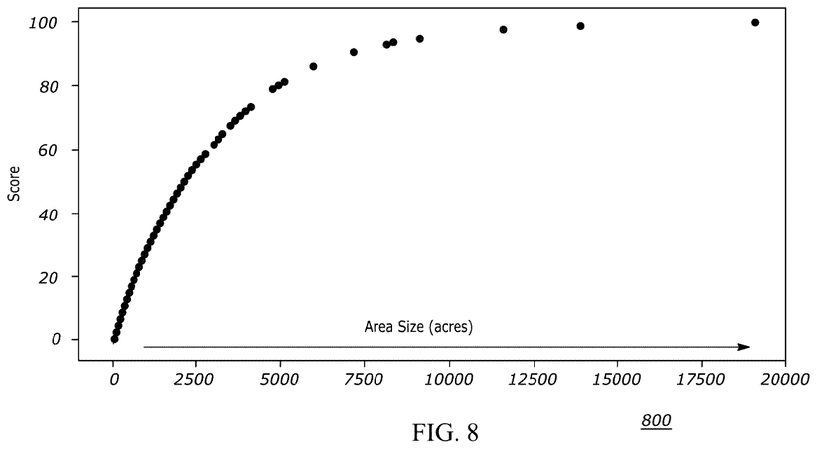

Turning to FIG. 7A and FIG. 7B are pictorial maps 700 of color-coded land score values with various filters, according to an example of the present invention. Land scores are overlaid on a map with darker colors designating higher land scores and lighter colors designating lower land scores.

### Land Score Components

In one example, different land scores are added that form appropriate cluster shapes and give a proper ranking of clusters. The system uses scoring to pick the best parcels within a cluster and rank the clusters based on land, transmission, resource, and market factors.

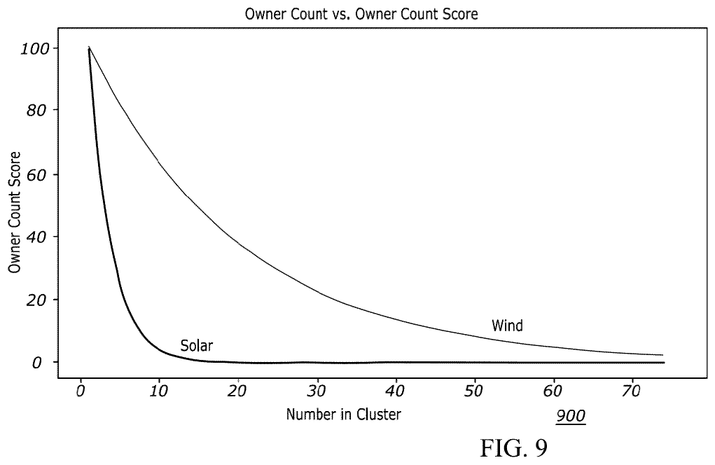

FIG. 8 is a graph 800 of a Parcel Size Score versus the landowner's parcel size, according to an example of the present invention.

The Parcel Size Score is designed to nudge the recommendations towards larger land parcels and larger swaths of single-owner occupied land. It is assigned based on the total buildable acreage by owner in the search radius of a starting parcel (0=tiny parcels, 100=giant single owner swaths of land). Each parcel gets assigned a Parcel Size Score based on the size of common parcels from each owner in the search radius, which influences which parcels get chosen by the clustering algorithm and favors the choice of big swaths of parcels from the same owner within the clustering algorithm. The score assigned to each parcel is based on the total owner area within the search radius. The equation uses a variable “parcel_size_cost_coefficient” which varies between wind/solar and modifies the steepness of the curve. For solar, the owner area size curve is steeper to prioritize differences at smaller parcel sizes. Each cluster's Parcel Size Score is the weighted area average of parcel size score, which favors clusters with large swaths of land.

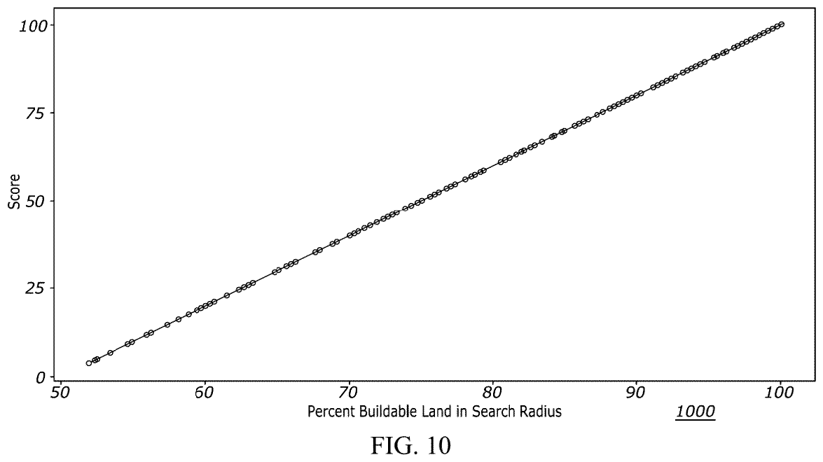

The Owner Count Score is meant to nudge the recommendations towards clusters of land parcels that have fewer landowners, preferably one. It is an exponentially decaying score with each additional landowner in a cluster, starting at a score of 100 for one owner and approaching zero for ten landowners for solar and 50 landowners for wind. The equation uses a variable “owner_score_coefficient” which varies between wind/solar and modifies the steepness of the curve, with a steeper curve for solar than wind that is designed to give more priority to minimizing the number of landowners for solar than for wind. FIG. 9 depicts a graph of Owner Count Score versus the number of owners 900, according to an example of the present invention. For solar, the owner score drops much faster to emphasize the greater need to minimize the number of landowners for solar compared to wind.

The Buildable Land Score is meant to nudge the recommendations towards clusters of land parcels that are in areas with fewer potential land constraints. A 0-100 score scores the amount of buildable land in the vicinity (0=least land, 100=most land), with a declining score for each percent of available buildable land. A typical range may be from 20% to 100% buildable.

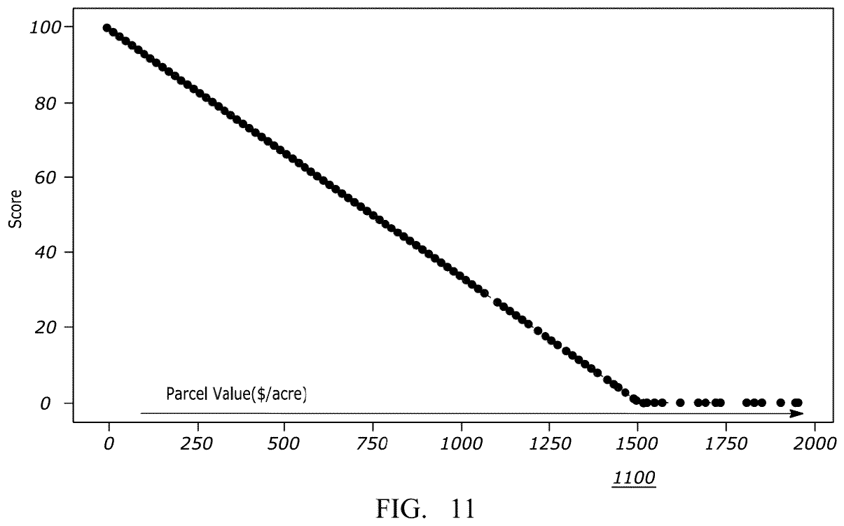

FIG. 10 depicts a graph of the score of a parcel of Buildable Land Score versus the percentage of buildable land in a search radius of 1000, according to an example of the present invention. In this example, 5 kilometers are used for wind, which is the approximate search radius fora 50 MW wind farm. As shown, the system favors clusters with large amounts of buildable land available in ranking.

The Land Cost Score is designed to shift the recommendations from the system away from areas that may have prohibitive construction costs. It is based on the percent of the buildable land that is not covered in trees, according to the US Forest Service Tree Canopy Cover Database. In one example, land cost score=100−2*percent tree coverage in buildable land of the parcel (e.g., 25% tree coverage on buildable land=land cost score of 50).

The Land Cost Score has increased weight as the Land Cost score decreases below a certain threshold (50%, which corresponds to 25% tree coverage), canceling out any benefit from large land parcels or a small number of landowners in a cluster. The goal here is to give a benefit to parcels/clusters with low tree coverage (high land cost score) while also having a prohibitive cost penalty once the tree cover exceeds a defined value so that large heavily tree-covered clusters (typically National/State Forest lands or timber company properties) are not favored by the system even if they have other favorable land characteristics such as a single owner.

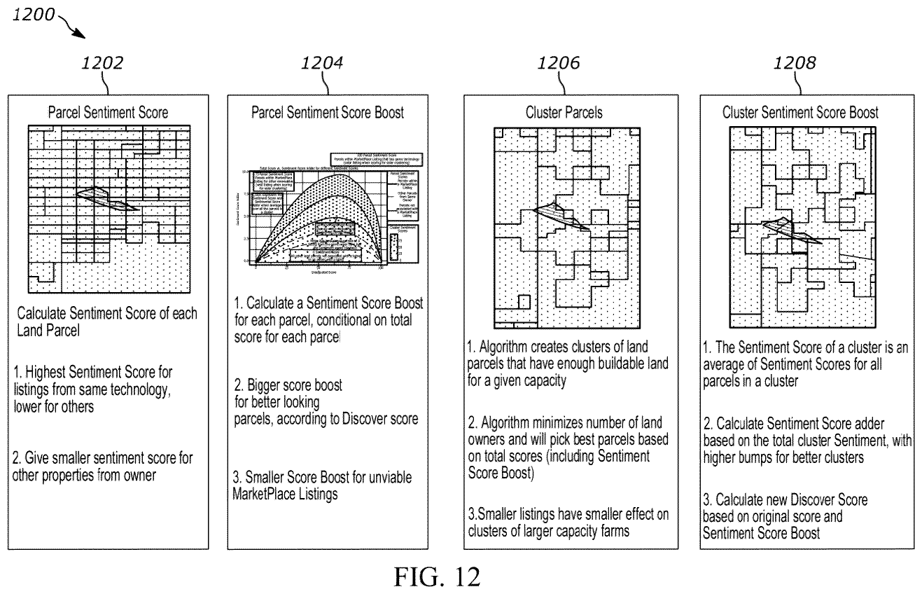

FIG. 11 depicts a graph of the score of a parcel of land versus a parcel value 1100, according to an example of the present invention.

### Low Score Escalators

Very poor land characteristics, very high transmission costs, or very low wind resources can have a very large negative impact on the viability of a recommended cluster, yet their scores can be relatively high if other score components are high. In order to increase the influence of these very low scores on the total score (and which particular clusters are recommended in the user interface), any land/transmission/resource score that is very low (<10) has a linearly increasing weight that also decreases the weight of other categories (to a minimum of 0.05). In this manner, a cluster with a transmission score of 0 will have a much lower score than if we just employ a strict average or weighted average.

### Sentiment Score Boost

The addition of third-party marketplace land listings advertisements from landowners about their desire to lease their land for wind, solar, or other mineral rights can help address another potential hurdle to renewable development: landowner sentiment. Combining these sentiment boost scores with the other scores described below provides users further insights into the main drivers of prospect viability.

Marketplace land listings, such as sentiment scoring, is used to prove a conditional score boost to land parcels (and clusters) that have landowners advertising their land for renewable (or other) leases on third-party websites marketplace land listings via a Sentiment Score Boost. The system also gives a partial Sentiment Score Boost to any additional land parcels nearby that the system identifies as owned by a landowner who advertised their land for energy leases.

The Sentiment Score Boost is applied to each parcel (100 if the listing is in the same technology being considered in the algorithm, 75 if it is another renewable technology, 50 if it is oil/gas/mining or other properties owned by a “lister”), apply a Sentiment Score Boost based on the total score of the parcel, cluster parcels together based on parcel scores and methods described previously, recalculate total scores, and then apply a sentiment boost to the cluster based on a weighted area average of the sentiment scores for parcels in the clusters.

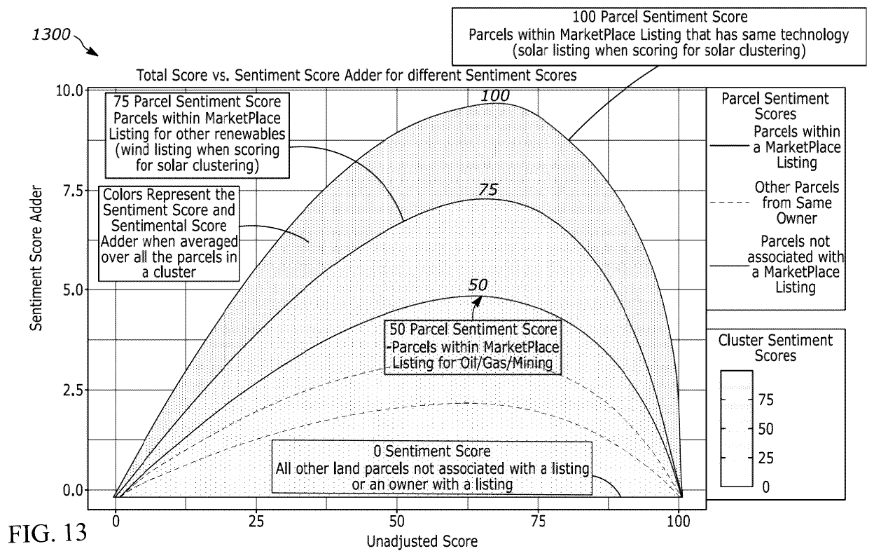

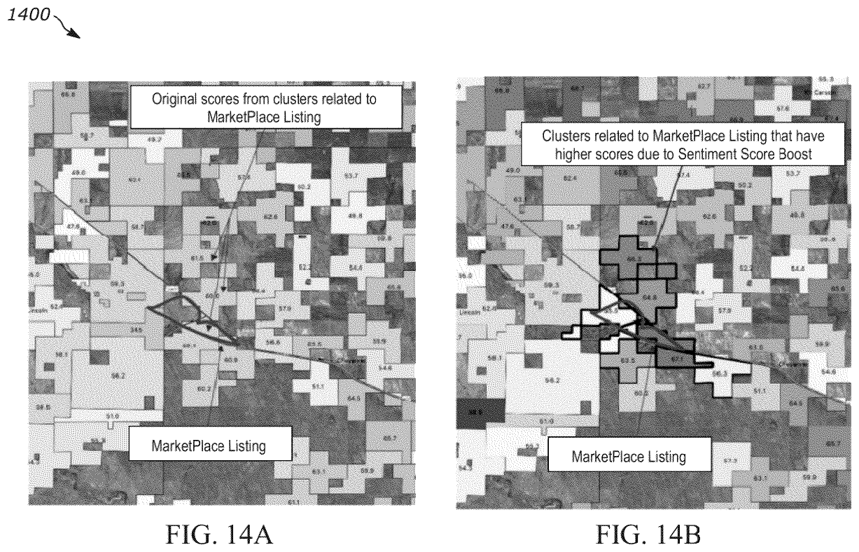

FIG. 12 depicts a series of pictorial diagrams 1200 representing parcel sentiment score 1202, parcel sentiment score boost 1204, parcel clustering 1206, and cluster sentiment score boost 1208. FIG. 13 depicts a graph of sentiment score adder versus unadjusted score 1300.

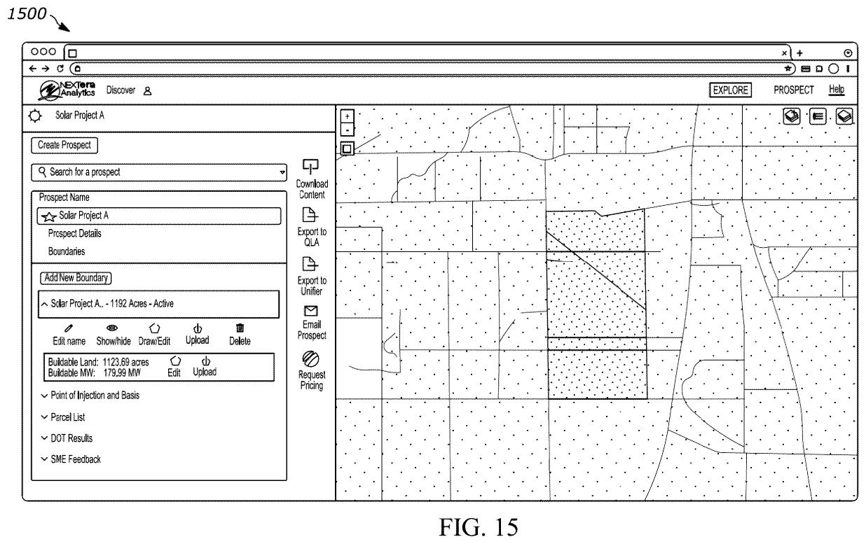

FIG. 14A and FIG. 14B are pictorial maps 1400 of color-coded sentiment boost score values with various filters, according to an example of the present invention. As described above, a marketplace listings of land is a database marketplace for listing sale or lease of land, that may include other information useful for developing new energy generation facilities such as wind, solar, battery, and SMRs

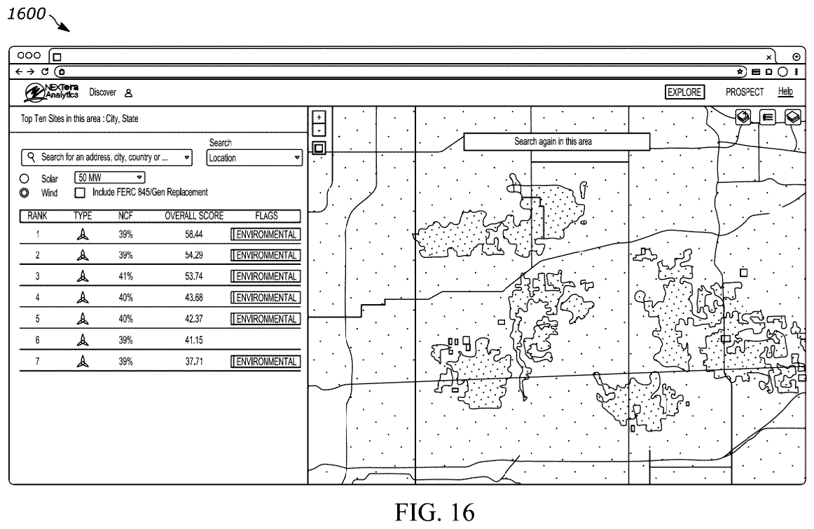

FIG. 15 is an example of an interactive graphical user interface 1500 that illustrates a pictorial map of color-coded solar prospects recommended by the system with buildable land highlighted, according to an example of the present invention.

### Score

Scores are normalized to a 0-100 scale by linearly stretching the distribution of weighted average scores.

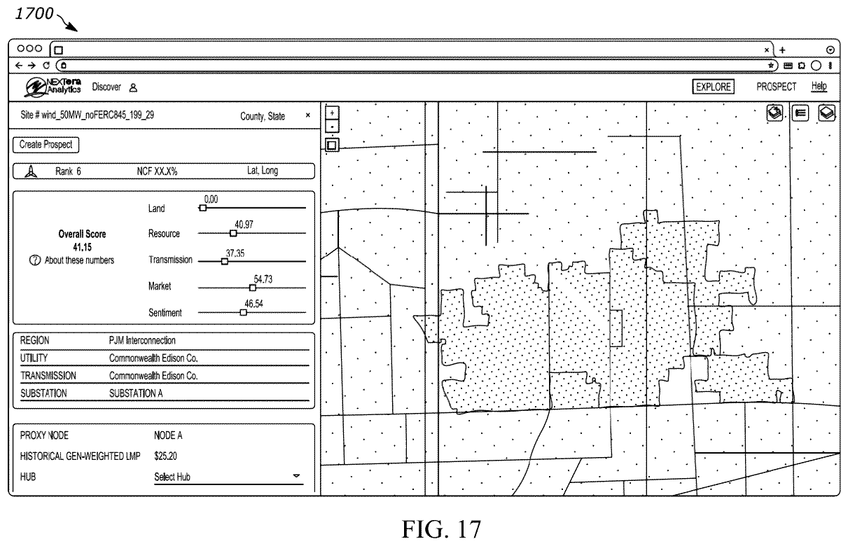

FIG. 16 is an example of an interactive graphical user interface 1600 that illustrates a pictorial map of color-coded recommended clusters of land parcels for wind project, including overall score characteristics, plus resource characteristics, land characteristics, transmission characteristics, and other sub-scores, according to an example of the present invention. Land parcels with a high sentiment score and a high score receive a larger sentiment score boost. The interactive graphical user interface with a map illustrates various clustering permutations of designs and the ranking. Not all the iterations that were evaluated need to be shown. Rather, only iterations that are improving iterations, i.e., the path of improvements, show only design returns in the highest combined score.

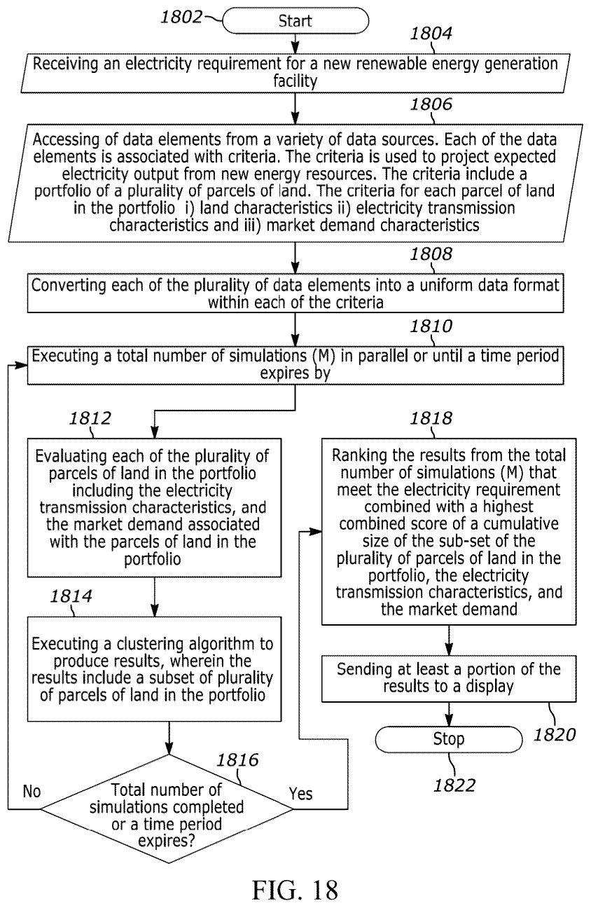

FIG. 17 is an example of a graphical user interface 1700 that illustrates a pictorial map of color-coded recommended clusters of land parcels for a wind project, including overall score characteristics, plus resource characteristics, land characteristics, transmission characteristics, and other sub-scores, according to an example of the present invention. As documented above, the system creates clusters of land parcels that have enough buildable land for a given capacity.

### Flow for Identifying Parcels of Land

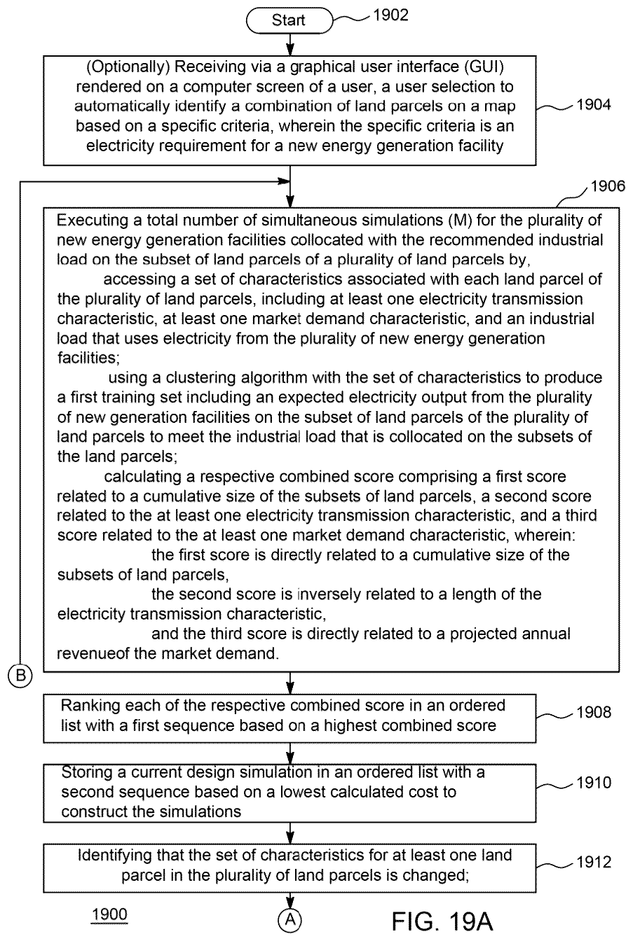

Turning now to FIG. 18, shown is a flow method 1800 for identifying parcels of land for an energy generation facility. The process begins in step 1802 and immediately proceeds to step 1804.

Step 1804 an electricity requirement is received fora new energy generation facility. This electricity requirement is typically expressed in megawatts of power. The process continues to step 1806.

In step 1806, data elements are accessed from a variety of data sources. Each of the data elements is associated with criteria. The criteria is used to project expected electricity output from new energy sources. The criteria include a portfolio of a plurality of parcels of land, each with i) land characteristics, ii) electricity transmission characteristics, and iii) market demand characteristics.

In one example, the criteria of land characteristics for each parcel of land in the portfolio may be any combination of electricity transmission characteristics of the parcel and market demand characteristics of the parcel. Further, these criteria may include any combination of the size of the parcel, ownership of the parcel, tree coverage in the parcel and/or tree clearing costs, the elevation of the parcel, terrain of the parcel, buildable land area of the parcel, location of the parcel to nearby renewable projects, or a landowner's willingness to grant rights to the parcel, i.e., sentiment score boost. Other criteria for each parcel of land in the portfolio may include the plurality of criteria that include at least one resource score, i.e., based on the availability of the resource at each parcel of land, e.g., based on the strength of the wind or solar in each of the parcels of land.

In another example, the criteria of transmission characteristics for each parcel of land in the portfolio may include the size of substation hardware costs, network upgrade costs, or grid tie-in costs. The process continues to step 1808.

In step 1808, each of the plurality of data elements is converted into a uniform data format within each of the criteria. The process continues to step 1810.

In step 1810, the process begins a loop in which a total number of simulations (M) are executed in parallel up to the total number of jobs or until a time period expires by step 1812 and step 1814.

In step 1812, each of the plurality of parcels of land in the portfolio is evaluated, including the land characteristics, the electricity transmission characteristics, and the market demand associated with the parcels of land in the portfolio. Next, in step 1814, a clustering algorithm is executed to produce results, wherein the results include a subset of the plurality of parcels of land in the portfolio. The process continues to step 1816. If the number of simulations is complete or the time period expires, the process continues to step 1818. Otherwise, the process returns to step 1810.

In step 1818, the results are ranked from the total number of simulations (M) that meet the electricity requirement combined with the highest combined score of a cumulative size of the subset of the plurality of parcels of land in the portfolio, the electricity transmission characteristics, and the market demand. The process continues to step 1820.

In step 1820, the results may be displayed in various formats with various color overlays on maps illustrating the combination of the parcels of land with the highest ranking for development based on the criteria. The process ends in step 1822.

### Training A Learning Algorithm

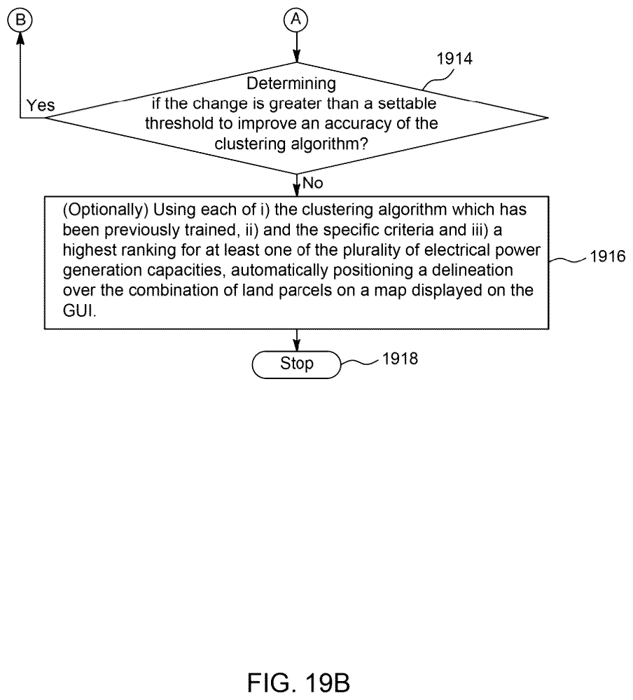

FIG. 19A and FIG. 19B is a flow chart 1900 for training a learning algorithm for simulated siting of a colocated new energy generation facility. The process begins in step 1902 and immediately proceeds to step 1904.

Step 1904 is an optional step in which a user selects via an interactive graphical user interface (GUI) rendered on a computer screen. Thea user selection automatically identifies a combination of land parcels on a map based on a specific criteria, wherein the specific criteria is an electricity requirement for a new energy generation facility. The process continues to step 1906.

Step 1906 is a loop. The method involves executing a series of simultaneous simulations (M) for a group of new energy generation facilities colocated with a recommended industrial load on selected land parcels. This process starts by accessing a set of characteristics for each land parcel, including at least one electricity transmission characteristic, one market demand characteristic, and an industrial load utilizing electricity from the energy facilities. Using these characteristics, a clustering algorithm generates a first training set that predicts the expected electricity output from the energy facilities on the subsets of land parcels, ensuring they meet the colocated industrial load requirements.

The method calculates a combined score for each subset, which includes a first score proportional to the cumulative size of the land parcel subsets, a second score inversely proportional to the length of the electricity transmission characteristic, and a third score directly proportional to the projected annual revenue from the market demand.

The set of characteristics may include at least one of tree clearing costs, whether each land parcel in the plurality of land parcels borders at least one of rivers, highways or both, proximity to fiber and transmission substations, or a combination thereof.

In the case of SMRs, the set of characteristics may include the size of each land parcel in the plurality of land parcels, tree coverage of each land parcel in the plurality land parcels, elevation of each land parcel in the plurality of land parcels, terrain of each land parcel in the plurality of land parcels, location of each land parcel in the plurality of land parcels to nearby renewable or small modular reactor projects, buildable land area of each land parcel in the plurality of land parcels, seismic risk, water availability, or a combination thereof.

The electricity transmission characteristic may include one or more of size of substation hardware costs, network upgrade costs, or grid tie-in costs.

In one example, a respective value based on a set of rules is assigned for each land parcel in the plurality of land parcels, for each of the at least one land characteristic, the at least one electricity transmission characteristic, the at least one market demand characteristic associated with each land parcel in the plurality of land parcels, and an owner's determined willingness to sell or lease rights to each land parcel in the plurality of land parcels. The clustering algorithm is executed to produce results that include the subset of land parcels in the plurality of land parcels. The clustering algorithm performs steps i) for each starting parcel exceeding a minimum size threshold, identify all other parcels within a distance threshold of the starting parcel: ii) assign a distance score for each other parcel based on its proximity to the starting parcel, the distance score being temporary for use by the clustering algorithm; iii) filter each land parcel in the plurality of land parcels based on at least one value generated for the parcel; iv) form a cluster including the starting parcel and at least one other parcel when the value of a land characteristic value meets a threshold, otherwise not form the cluster; and v) assigning a plurality of values for each formed cluster at least one value based on the owner's determined willingness to sell or lease rights of at least one parcel in each formed cluster.

The electricity transmission characteristic may include one or more of the size of substation hardware costs, network upgrade costs, or grid tie-in costs. The process continues to step 1908.

In step 1908, each of the subsets of land parcels is ranked that meet an electricity requirement for the new energy generation facility combined with the highest combined score of each of a a) cumulative size of the subsets of land parcels, b) the at least one electricity transmission characteristic, and c) the at least one market demand characteristic. The ranking may include reducing the ranking for any land parcel that borders at least one of rivers, highways or both. The process continues to step 1910.

Step 1910 each of the respective combined scores are ranked in an ordered list with a first sequence based on a highest combined score. The process continues to step 1912.

In step 1912, any change in the set of characteristics for at least one land parcel in the plurality of land parcels is identified. The process continues to step 1914.

In step 1914, a test is made to determine if the change is greater than a settable threshold to improve the accuracy of the clustering algorithm. For example, if a high percentage of renewable projects fail due to poor market conditions, then the weighting of the algorithm is modified to influence market-based factors more. In response to the change being greater than the settable threshold, the clustering algorithm is retrained by re-executing steps 1908 to 1914, as shown, by using the changed set of characteristics as a second training set. Otherwise, if the change is lower than or equal to the threshold, the process continues to step 1916.

Step 1916 is an optional step. Using each of i) the clustering algorithm which has been previously trained, ii) the specific criteria, and iii) the highest ranking for at least one of the plurality of electrical power generation capacities, automatically positioning a delineation over the combination of land parcels on a map displayed on the GUI. The process continues to step 1918, where it ends.

In another example, the process may further include performing a plurality of electricity output projections and related profitability. A plurality of data elements is accessed, each associated with one of a plurality of criteria, and each of the plurality of criteria is used to project expected electricity output from at least one of a plurality of new energy sources. The plurality of criteria includes i) for each of the plurality of electrical power generation capacities, an amount of buildable land on each land parcel in the plurality of land parcels, ii) ownership of each land parcel in the plurality of land parcels, iii) at least one electricity transmission characteristic of each land parcel in the plurality of land parcels, and iv) at least one market demand characteristic of each of the land parcel in the plurality of land parcels; and v) wherein for each of the land parcel in the plurality of land parcels, the plurality of criteria further includes at least one resource score based on the strength of wind or solar in each land parcel in the plurality of land parcels.

One challenging aspect of energy project development is assessing landowner sentiment-specifically, whether the owner of a particular parcel of land is willing to host an energy generation facility. Landowner sentiment is a critical factor and a common reason for project failure.

For instance, a trained algorithm may recommend a parcel as suitable for development. However, during the process of engaging with landowners, the developer might discover that none of the local landowners are interested in accommodating solar installations on their property. In such cases, the system incorporates this new information and adjusts the ranking by removing the parcel from consideration.

Another optional feature is using land characteristics to score higher contiguous areas of land or land nearest a starting point. This is calculated using a nearest-neighbor algorithm as part of the ranking.

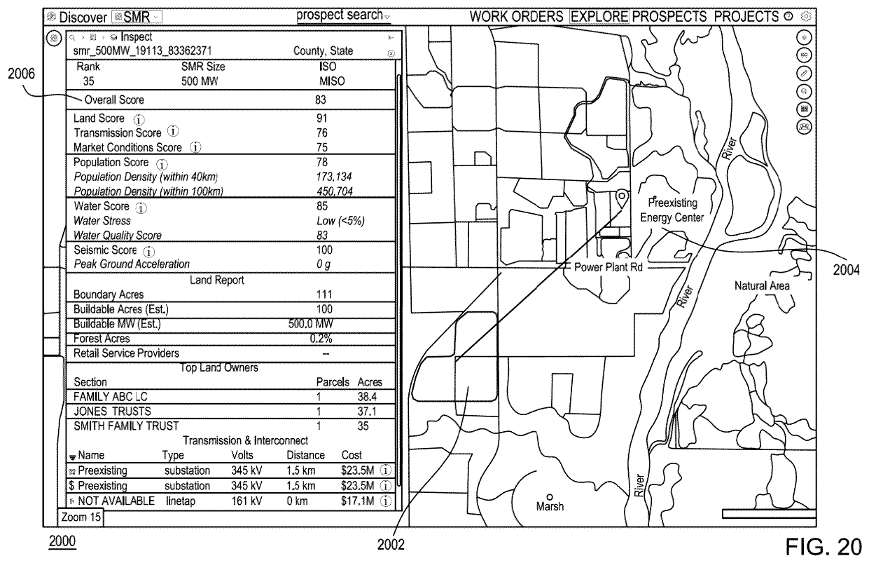

FIG. 20 is an example of an interactive graphical user interface (GUI) 2000 that illustrates a delineated set of land parcels recommended for a new small modular reactor (SMR) site, including overall score characteristics, plus scores for resource characteristics, land characteristics, and transmission characteristics, as well as landowner sentiment.

### Implementations of Algorithm

The present invention can be implemented on a standalone computer system, a server, a web-server, a cloud computing system, a hybrid cloud system, or other on-demand availability of computer system resources, especially data storage and computing power, without direct active management by the user.

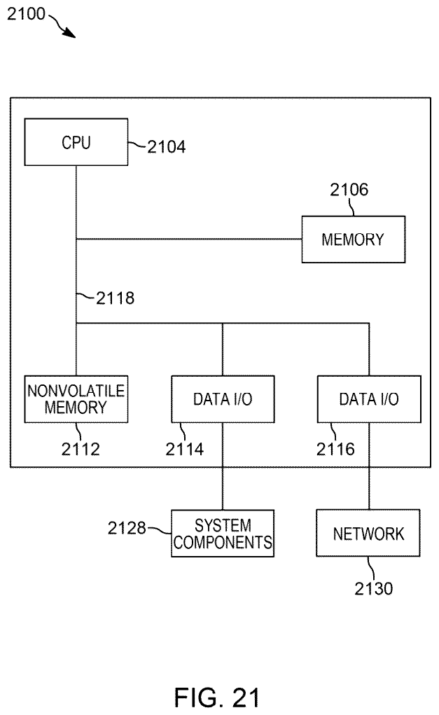

FIG. 21 illustrates a block diagram illustrating a processing system 2100 for carrying out a portion of the present invention, according to an example. The processor system 2100 is an example of a processing subsystem that is able to perform any of the above-described processing operations, other operations, or combinations of these, such as the flow diagram of FIG. 21.

The processor 2100 in this example includes a hardware processor or CPU 2104 that is communicatively connected to a main memory 2106 (e.g., volatile memory), a non-volatile memory 2112 to support processing machine instruction and operations. The CPU is further communicatively coupled to a network adapter hardware 2116 to support input and output communications with external computing systems such as through the illustrated network 2130.

The processor 2100 further includes a data input/output (I/O) processor 2114 that can be adapted to communicate with any type of equipment, such as the illustrated system components 2128. The data input/output (I/O) processor, in various examples, can be con figured to support any type of data communication connection, including present-day analog and/or digital techniques or via a future communications mechanism. A system bus 2118 interconnects these system components.

### Information Processing System

The present subject matter can be realized in hardware, software, or a combination of hardware and software. A system can be realized in a centralized fashion in one computer system or in a distributed fashion where different elements are spread across several interconnected computer systems Any kind of computer system—or other apparatus adapted for carrying out the methods described herein—is suitable. A typical combination of hardware and software could be a general-purpose computer system with a computer program that, when being loaded and executed, controls the computer system such that it carries out the methods described herein.

The present subject matter can also be embedded in a computer program product, which comprises all the features enabling the implementation of the methods described herein and which—when loaded in a computer system—is able to carry out these methods. The computer program in the present context means any expression, in any language, code, or notation, of a set of instructions intended to cause a system having an information processing capability to perform a particular function either directly or after either or both of the following a) conversion to another language, code or notation; and b) reproduction in a different material form.

Each computer system may include, inter alia, one or more computers and at least a computer readable medium allowing a computer to read data, instructions, messages or message packets, and other computer readable information from the computer readable medium. The computer readable medium may include computer readable storage medium embodying non-volatile memory, such as read-only memory (ROM), flash memory, disk drive memory, CD-ROM, and other permanent storage. Additionally, a computer medium may include volatile storage such as RAM, buffers, cache memory, and network circuits. Furthermore, the computer readable medium may comprise computer readable information in a transitory state medium such as a network link and/or a network interface, including a wired network or a wireless network, that allows a computer to read such computer readable information. In general, the computer readable medium embodies a computer program product as a computer readable storage medium that embodies computer readable program code with instructions to control a machine to perform the above-described methods and realize the above-described systems.

### Non-Limiting Examples

Although specific embodiments of the subject matter have been disclosed, those having ordinary skill in the art will understand that changes are made to the specific embodiments without departing from the spirit and scope of the disclosed subject matter. The scope of the disclosure is not to be restricted, therefore, to the specific embodiments, and it is intended that the appended claims cover any and all such applications, modifications, and embodiments within the scope of the present disclosure.

All references listed in the information disclosure statement (IDS) are hereby incorporated by reference in their entirety.

1. A computer-implemented method for training a learning algorithm for simulated siting of a plurality of new energy generation facilities colocated with a recommended industrial load on a subset of land parcels of a plurality of land parcels, the method comprising:
i) executing a total number of simultaneous simulations (M) for the plurality of new energy generation facilities colocated with the recommended industrial load on the subset of land parcels of a plurality of land parcels by,
accessing a set of characteristics associated with each land parcel of the plurality of land parcels, including at least one electricity transmission characteristic, at least one market demand characteristic, and an industrial load that uses electricity from the plurality of new energy generation facilities;
using a clustering algorithm with the set of characteristics to produce a first training set including an expected electricity output from the plurality of new energy generation facilities on the subset of land parcels of the plurality of land parcels to meet the industrial load that is colocated on the subsets of the land parcels;
calculating a respective combined score comprising a first score related to a cumulative size of the subsets of land parcels, a second score related to the at least one electricity transmission characteristic, and a third score related to the at least one market demand characteristic, wherein:
the first score is directly related to a cumulative size of the subsets of land parcels,
the second score is inversely related to a length of the electricity transmission characteristic,
and the third score is directly related to a projected annual revenue of the market demand;
ii) ranking each of the respective combined score in an ordered list with a sequence based on a highest combined score;
iii) storing a current design simulation in an ordered list with a second sequence based on a lowest calculated cost to construct the simulations;
iv) identifying that the set of characteristics for at least one land parcel in the plurality of land parcels is changed;
v) determining if the change is greater than a settable threshold to improve an accuracy of the clustering algorithm; and
vi) in response to the change being greater than the settable threshold, re-training the clustering algorithm that has been trained by the first training set by re-executing steps i) through iv) using the changed set of characteristics as a second training set.

2. The computer-implemented method of claim 1, wherein the recommended industrial load is a new prospective industrial load, a preexisting industrial load, or a preexisting industrial load that is being updated.

3. The computer-implemented method of claim 1, wherein the ii) executing the total number of simultaneous simulations (M) further comprises:
assigning a respective value based on a set of rules, for each land parcel in the plurality of land parcels, for each of the at least one land characteristic, the at least one electricity transmission characteristic, the at least one market demand characteristic associated with each land parcel in the plurality of land parcels, and an owner's determined willingness to sell or lease rights to each land parcel in the plurality of land parcels; and
executing the clustering algorithm to produce results that include the subset of land parcels in the plurality of land parcels, wherein the clustering algorithm performs steps comprising:
for each starting parcel exceeding a minimum size threshold, identify all other parcels within a distance threshold of the starting parcel;
assign a distance score for each other parcel based on its proximity to the starting parcel, the distance score being temporary for use by the clustering algorithm;
filter each land parcel in the plurality of land parcels based on at least one value generated for the parcel;
form a cluster including the starting parcel and at least one other parcel when the value of a land characteristic value meets a threshold, otherwise not form the cluster; and
assigning a plurality of values for each formed cluster at least one value based on the owner's determined willingness to sell or lease rights of at least one parcel in each formed cluster.

4. The computer-implemented method of claim 1, further comprising:
receiving via a graphical user interface (GUI) rendered on a computer screen of a user, a user request to automatically identify a combination of land parcels on a map based on a specific criteria, wherein the specific criteria is an electricity requirement for a new energy generation facility; and
using each of i) the clustering algorithm which has been previously trained, ii) and the specific criteria and iii) a highest ranking for each of the subsets of land parcels that meet an electricity requirement for the new energy generation facility to meet the recommended industrial load that is colocated on the subsets of the land parcels, automatically generating and positioning a delineation over the combination of land parcels on a map displayed in the GUI.

5. The computer-implemented method of claim 1, wherein the executing the total number of simulations (M) are executed in parallel up to a total number of jobs or until a time period expires.

6. The computer-implemented method of claim 5, wherein the total number of simulations, the time period, or both are settable by a user.

7. The computer-implemented method of claim 1, wherein for each land parcel in the plurality of land parcels, the set of characteristics includes tree clearing costs.

8. The computer-implemented method of claim 4, wherein for each land parcel in plurality of land parcels, the set of characteristics includes whether the each land parcel in the plurality of land parcels borders at least one of rivers, highways or both, and wherein the ranking from the total number of simulations (M) includes reducing the ranking for any land parcel that borders the at least one of rivers, highways or both.

9. The computer-implemented method of claim 1, further comprising:
performing a plurality of electricity output projections by:
accessing a plurality of data elements, each associated with one of a plurality of criteria, and each of the plurality of criteria is used to project expected electricity output from at least one of a plurality of new energy sources, and the plurality of criteria includes
for each of a plurality of electrical power generation capacities, an amount of buildable land on each land parcel in the plurality of land parcels,
ownership of each land parcel in the plurality of land parcels,
at least one electricity transmission characteristic of each land parcel in plurality of land parcels, and
at least one market demand characteristic of each of the land parcel in the plurality of land parcels; and
wherein for each of the land parcel in the plurality of land parcels, the plurality of criteria further includes at least one resource score based on a strength of wind or solar in each land parcel in the plurality of land parcels.

10. The computer-implemented method of claim 9, wherein the ownership of each land parcel in the plurality of land parcels and an owner's determined willingness to sell or lease rights to the parcel based on data received from a third party system.

11. The computer-implemented method of claim 9, wherein the plurality of criteria includes one or more of
a size of each land parcel in the plurality of land parcels,
tree coverage of each land parcel in the plurality land parcels,
elevation of each land parcel in the plurality of land parcels,
terrain of each land parcel in the plurality of land parcels,
location of each land parcel in the plurality of land parcels to nearby renewable projects,
buildable land area of each land parcel in the plurality of land parcels,
population density of each land parcel in the plurality of land parcels,
water scarcity or quality of each land parcel in the plurality of land parcels,
proximity to rail or highway of each land parcel; or
a combination thereof.

12. The computer-implemented method of claim 1, wherein for each land parcel in the plurality of land parcels, the at least one electricity transmission characteristic includes one or more of size of substation hardware costs, network upgrade costs, or grid tie-in costs.

13. The computer-implemented method of claim 1, wherein for each land parcel in the plurality of land parcels, the at least one market characteristic includes one of locational marginal prices and/or the simulation of annual revenue from hourly fluctuations of a combination of locational marginal prices, wind resource, solar resource, industrial load, or a combination thereof.

14. The computer-implemented method of claim 1, wherein the expected electricity output is for new renewable solar energy sources.

15. The computer-implemented method of claim 1, wherein the expected electricity output is for a new renewable wind energy sources.

16. A system for training a learning algorithm for simulated siting of a plurality of new energy generation facilities colocated with a recommended industrial load on a subset of land parcels of a plurality of land parcels, the system comprising:
a computer memory capable of storing machine instructions; and
a hardware processor in communication with the computer memory, the hardware processor configured to access the computer memory to execute machine instructions for
i) executing a total number of simultaneous simulations (M) for the plurality of new energy generation facilities colocated with the recommended industrial load on the subset of land parcels of a plurality of land parcels by,
accessing a set of characteristics associated with each land parcel of the plurality of land parcels, including at least one electricity transmission characteristic, at least one market demand characteristic, and an industrial load that uses electricity from the plurality of new energy generation facilities;
using a clustering algorithm with the set of characteristics to produce a first training set including an expected electricity output from the plurality of new energy generation facilities on the subset of land parcels of the plurality of land parcels to meet the industrial load that is colocated on the subsets of the land parcels;
calculating a respective combined score comprising a first score related to a cumulative size of the subsets of land parcels, a second score related to the at least one electricity transmission characteristic, and a third score related to the at least one market demand characteristic, wherein:
the first score is directly related to a cumulative size of the subsets of land parcels,
the second score is inversely related to a length of the electricity transmission characteristic,
and the third score is directly related to a projected annual revenue of the market demand;
ii) ranking each of the respective combined score in an ordered list with a sequence based on a highest combined score;
iii) storing a current design simulation in an ordered list with a second sequence based on a lowest calculated cost to construct the simulations;
iv) identifying that the set of characteristics for at least one land parcel in the plurality of land parcels is changed;
v) determining if the change is greater than a settable threshold to improve an accuracy of the clustering algorithm; and
vi) in response to the change being greater than the settable threshold, re-training the clustering algorithm that has been trained by the first training set by re-executing steps i) through iv) using the changed set of characteristics as a second training set.

17. The system of claim 16, wherein the recommended industrial load is a new prospective industrial load, a preexisting industrial load, or a preexisting industrial load that is being updated.

18. The system of claim 16, wherein the ii) executing the total number of simultaneous simulations (M) further comprises:
assigning a respective value based on a set of rules, for each land parcel in the plurality of land parcels, for each of the at least one land characteristic, the at least one electricity transmission characteristic, the at least one market demand characteristic associated with each land parcel in the plurality of land parcels, and an owner's determined willingness to sell or lease rights to each land parcel in the plurality of land parcels; and
executing the clustering algorithm to produce results that include the subset of land parcels in the plurality of land parcels, wherein the clustering algorithm performs steps comprising:
for each starting parcel exceeding a minimum size threshold, identify all other parcels within a distance threshold of the starting parcel;
assign a distance score for each other parcel based on its proximity to the starting parcel, the distance score being temporary for use by the clustering algorithm;
filter each land parcel in the plurality of land parcels based on at least one value generated for the parcel;
form a cluster including the starting parcel and at least one other parcel when the value of a land characteristic value meets a threshold, otherwise not form the cluster; and
assigning a plurality of values for each formed cluster at least one value based on the owner's determined willingness to sell or lease rights of at least one parcel in each formed cluster.

19. The system of claim 16, further comprising:
receiving via a graphical user interface (GUI) rendered on a computer screen of a user, a user request to automatically identify a combination of land parcels on a map based on a specific criteria, wherein the specific criteria is an electricity requirement for a new energy generation facility; and
using each of i) the clustering algorithm which has been previously trained, ii) and the specific criteria and iii) a highest ranking for each of the subsets of land parcels that meet an electricity requirement for the new energy generation facility to meet the recommended industrial load that is colocated on the subsets of the land parcels, automatically generating and positioning a delineation over the combination of land parcels on a map displayed in the GUI.

20. The system of claim 16, further comprising, further comprising:
performing a plurality of electricity output projections by:
accessing a plurality of data elements, each associated with one of a plurality of criteria, and each of the plurality of criteria is used to project expected electricity output from at least one of a plurality of new energy sources, and the plurality of criteria includes
for each of a plurality of electrical power generation capacities, an amount of buildable land on each land parcel in the plurality of land parcels,
ownership of each land parcel in the plurality of land parcels,
at least one electricity transmission characteristic of each land parcel in plurality of land parcels, and
at least one market demand characteristic of each of the land parcel in the plurality of land parcels; and
wherein for each of the land parcel in the plurality of land parcels, the plurality of criteria further includes at least one resource score based on a strength of wind or solar in each land parcel in the plurality of land parcels.
